(19) United States
(12) Patent Application Publication
(10) Pub. No.: US 2015/0303283 A1
(43) Pub. Date: Oct. 22, 2015

(54) METHOD FOR MANUFACTURING SEMICONDUCTOR DEVICE

(71) Applicant: UNITED MICROELECTRONICS CORP., Hsin-Chu City (TW)

(72) Inventors: Chin-Cheng Chien, Tainan City (TW); Chun-Yuan Wu, Yun-Lin County (TW); Ted Ming-Lang Guo, Tainan City (TW)

(73) Assignee: UNITED MICROELECTRONICS CORP., Hsin-Chu City (TW)

(21) Appl. No.: 14/279,340

(22) Filed: May 16, 2014

(30) Foreign Application Priority Data
Apr. 22, 2014 (CN) 201410163083.6

(51) Int. Cl. H01L 29/66

(52) U.S. Cl. CPC H01L 29/66803

(57) ABSTRACT

A method for manufacturing a semiconductor device includes the following steps. A substrate including at least a fin layer and a plurality of gate electrodes is provided. A tilt and twist ion implantation is performed to form a plurality of doped regions in the fin layer. An etching process is performed to remove the doped regions to form a plurality of recesses in the fin layer.

### BACKGROUND OF THE INVENTION

1. Field of the Invention

The present invention relates to a method for manufacturing a semiconductor device, and more particularly, to a method for manufacturing a fin field effect transistor (hereinafter abbreviated as FinFET) device.

2. Description of the Prior Art

Conventional planar metal-oxide-semiconductor (MOS) transistor has difficulty when scaling down to 65 nm and below. Therefore the non-planar transistor technology such as FinFET technology that allows smaller size and higher performance is developed to replace the planar MOS transistor.

In the prior art, the conventional FinFET device is formed by: first a silicon layer is patterned to form a fin film in the SOI substrate by any proper etching process. Then, a gate including an insulating layer such as a high dielectric constant (high-k) layer and a gate conductive layer is formed to cover portions of the fin film. Next, ion implantation and anneal treatment are performed to form a source/drain in the fin film not covered by the gate. Since the manufacturing processes of the FinFET device are easily integrated into the traditional logic device processes, it provides superior process compatibility. Furthermore, when the FinFET device is formed on the SOI substrate, traditional shallow trench isolation (STI) is no longer in need. More important, since the FinFET device increases the overlapping area between the gate and the substrate, the channel region is more effectively controlled. This therefore reduces drain-induced barrier lowering (DIBL) effect and short channel effect. In addition, the channel region is longer under the same gate length, and thus the current between the source and the drain is increased.

However, needs for improving performance of the FinFET device are still to be satisfied. For example, it is always desirable to induce stress to enhance carrier mobility of the channel region of the FinFET device.

### SUMMARY OF THE INVENTION

According to an aspect of the present invention, a method for manufacturing a semiconductor device is provided. The method includes the following steps. A semiconductor substrate is provided. The semiconductor substrate includes at least a fin layer and a plurality of gate electrodes formed thereon. A tilt and twist ion implantation is then performed to form a plurality of doped regions in the fin layer. After forming the doped regions, an etching process is performed to remove the doped regions to form a plurality of recesses in the fin layer.

According to the method for manufacturing the semiconductor device provided by the present invention, the tilt and twist ion implantation is performed to form the doped regions in the fin layer. An etching rate of the doped regions is different from an etching rate of the fin layer. Therefore, the doped regions are easily removed by the etching process. More important, the etching process is to etch the doped regions along its profile, and thus the recesses are obtained with the special profiles. Furthermore, epitaxial layers are to be formed in the recesses, and thus effective stress to the channel region provided by the selective strain scheme is further enhanced. Consequently, electrical performance of the semiconductor device is improved according to the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6B are schematic drawings illustrating a method for manufacturing a semiconductor device provided by a preferred embodiment of the present invention, wherein

FIG. 2A is a cross-sectional view taken along Line A-A′ of FIG. 1;

FIG. 2B is a cross-sectional view taken along Line B-B′ of FIG. 1;

FIG. 3 is a schematic drawing illustrating a tilt angle and a twist angle of a semiconductor substrate with respect to an ion beam in a tilt and twist ion implantation;

FIG. 4A is a schematic drawing in a step subsequent to FIG. 2A;

FIG. 4B is a schematic drawing in a step subsequent to FIG. 2B;

FIG. 5A is a schematic drawing in a step subsequent to FIG. 4A;

FIG. 5B is a schematic drawing in a step subsequent to FIG. 4B;

FIG. 6A is a schematic drawing in a step subsequent to FIG. 5A; and

FIG. 6B is a schematic drawing in a step subsequent to FIG. 5B.

### DETAILED DESCRIPTION

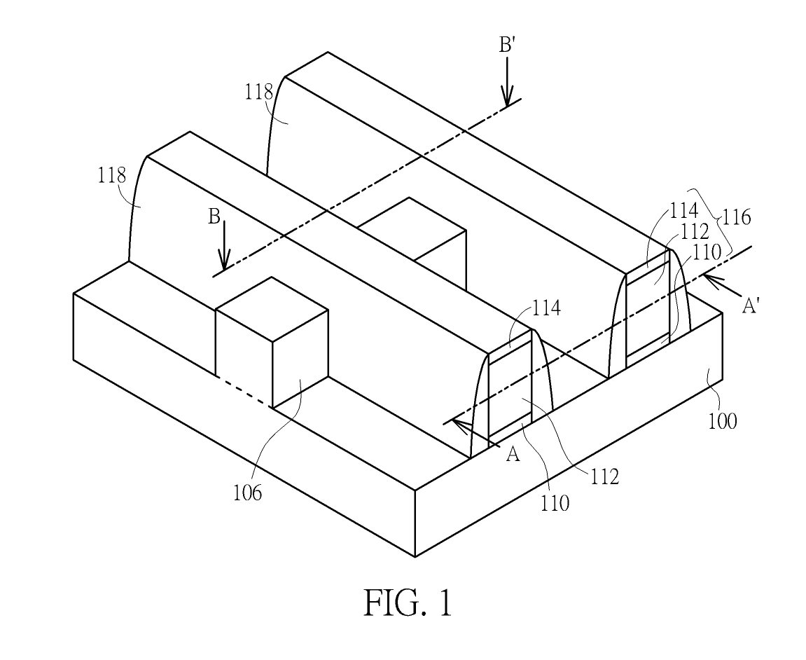

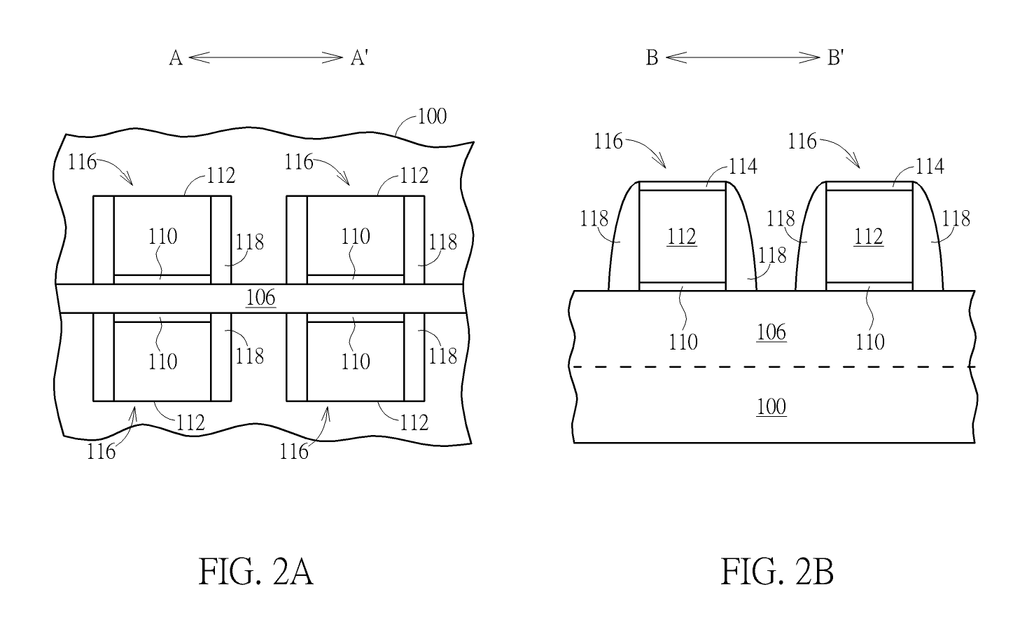

Please refer to FIGS. 1-6B, which are drawings illustrating a method for manufacturing a semiconductor device provided by a preferred embodiment of the present invention. Please refer to FIGS. 1-2B first, wherein FIG. 2A is a cross-sectional view taken along Line A-A′ of FIG. 1 and FIG. 2B is a cross-sectional view taken along Line B-B′ of FIG. 1. According to the method for manufacturing a semiconductor device provided by the preferred embodiment, a semiconductor substrate 100 is provided. The semiconductor substrate 100 can include a silicon-on-insulator (SOI) substrate. It is well-known to those skilled in the art that the SOI substrate upwardly includes a silicon substrate, a bottom oxide (BOX) layer and a semiconductor layer such as a single crystalline silicon layer formed on the BOX layer. However, for providing superior ground connection and thermal dissipation and for reducing interference and cost, the semiconductor substrate 100 provided by the preferred embodiment also can include a bulk silicon substrate as shown in FIG. 1.

Please refer to FIGS. 1-2B again. Next, a patterned hard mask (not shown) for defining at least a fin layer for a multi-gate transistor device is formed on the semiconductor substrate 100 and followed by performing an etching process. Thus, a portion of the semiconductor material of the semiconductor substrate 100 is removed to form at least a patterned semiconductor layer, that is a fin layer 106, on the semiconductor substrate 100. It is noteworthy that, in the preferred embodiment, the fin layer 106 includes a crystalline orientation, and the crystalline orientation is (100).

Please still refer to FIGS. 1-2B. After forming the fin layer 106, the patterned hard mask is removed. Subsequently, a dielectric layer 110, a gate conductive layer 112 and a patterned hard mask 114 are sequentially formed on the semiconductor substrate 100, and followed by patterning the dielectric layer 110 and the gate conductive layer 112 through the patterned hard mask 114. Consequently, a plurality of gate electrodes 116 are formed on the semiconductor substrate 100. The gate electrodes 116 cover portions of the fin layer 106. An extension direction of the gate electrodes 116 is perpendicular to an extension direction of the fin layer 106 as shown in FIG. 1. The dielectric layer 110 includes the conventional dielectric material such as silicon oxide (SiO), silicon nitride (SiN), or silicon oxynitride (SiON). In the preferred embodiment, the dielectric layer 110 can further include high-K dielectric material such as hafnium oxide (HfO), hafnium silicate (HfSiO), or metal oxide or metal silicate exemplarily of aluminum (Al), zirconium (Zr), lanthanum (La), but not limited to this. In addition, when the dielectric layer 110 of the preferred embodiment adopts the high-K dielectric material, the present invention can be further integrated to the metal gate process. Therefore control gate compatible to the high-K gate dielectric layer is obtained. Accordingly, the gate electrodes 116 can include different materials according to the gate-first or gate-last process. For example, when the preferred embodiment is integrated to the gate-first process, the gate conductive layer 112 includes metal such as tantalum (Ta), titanium (Ti), ruthenium (Ru), molybdenum (Mo), alloys of the aforementioned metals, metal nitride such as tantalum nitride (TaN), titanium nitride (TiN), molybdenum nitride (MoN), or metal carbide such as tantalum carbide (TaC). It is noteworthy that the metals are chosen by providing proper work function to the multi-gate transistors of different conductivity types. And the gate conductive layer 112 can be a single-layered or multi-layered structure. When the preferred embodiment is integrated to the gate-last process, the gate conductive layer 112 serves as a dummy gate and includes semiconductor material such as polysilicon.

Please still refer to FIGS. 1-2B. After forming the gate electrodes 116, source/drain extension regions (not shown) can be formed in the fin layer 106 if required. Subsequently, a spacer 118 is formed on two opposite sidewalls of the gate electrodes 116, respectively. The spacer 118 can be a single-layered or multi-layered structure.

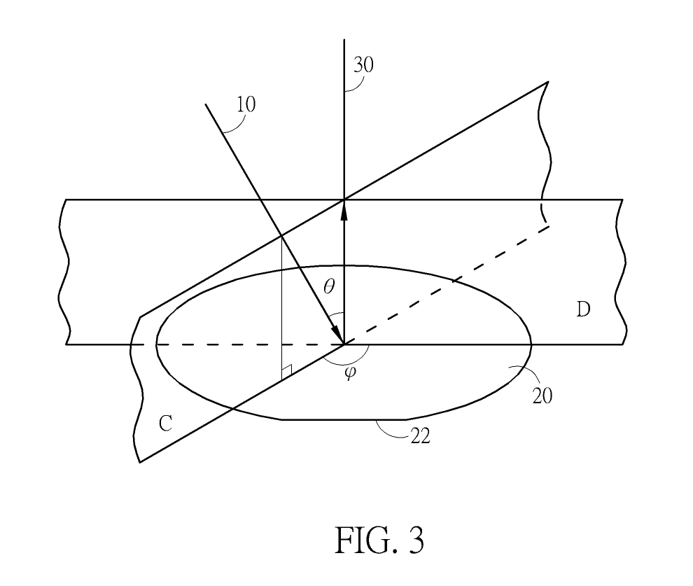

Please refer to FIG. 3, which is a schematic drawing illustrating a tilt angle and a twist angle of a semiconductor substrate with respect to an ion beam in a tilt and twist ion implantation. As shown in FIG. 3, the manner in which an ion beam 10 strikes a semiconductor wafer 20 is defined by a tilt angle θ and a twist angle φ. The angle between the incident ion beam 10 and an axial 30 which is vertical to a surface of the semiconductor wafer 20 is defined as the tilt angle θ. And the twist angle φ is the angle between a plane C and a plane D. The plane C contains the ion beam 10 and the axial 30. The plane D is parallel with a wafer flat 22, and perpendicular to the surface of the semiconductor wafer 20. It is therefore understood that the tilt angle θ and the twist angle φ are angular components of the incidence angle of the ion beam 10. When the tilt angle θ or/and the twist angle φ change, profile and depth of the region to which the ion beam 10 strikes change accordingly. In other words, the tilt angle θ and the twist angle φ are extremely important parameters in the ion implantation.

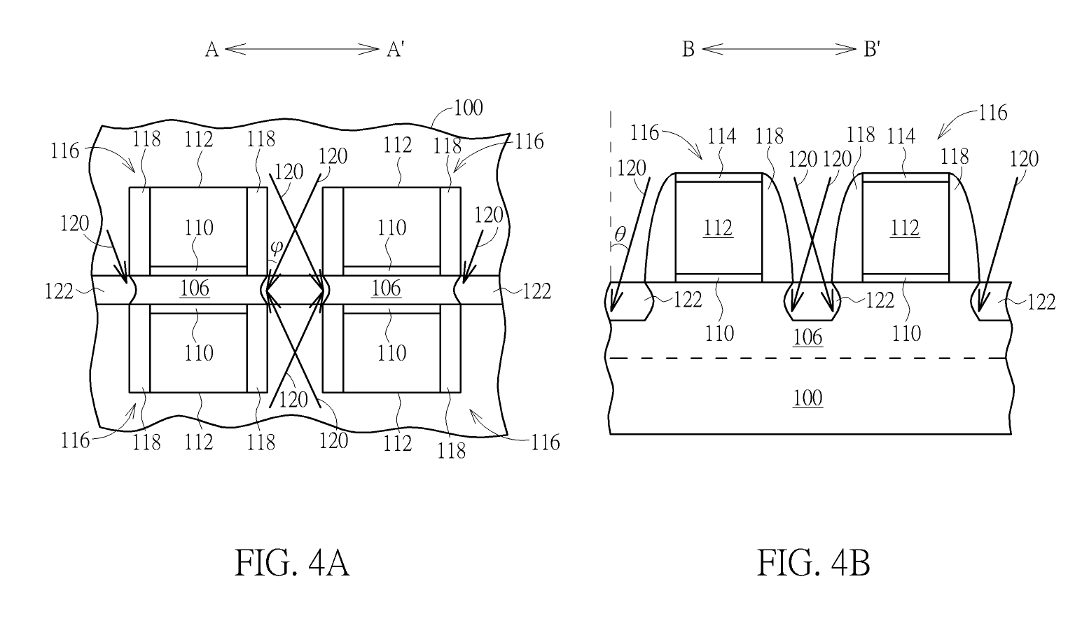

Please refer to FIGS. 4A and 4B. After forming the spacer 118, a tilt and twist ion implantation 120 is performed according to the preferred embodiment. As mentioned above, the tilt angle θ and the twist angle φ affect profile and depth of the region to which the ion beam strikes, the tilt angle θ and the twist angle φ are therefore particularly noticed in the preferred embodiment: The tilt and twist ion implantation 120 includes a tilt angle θ and a twist angle φ. The tilt angle θ is adjusted according to a height of the gate electrodes 116. The tilt angle θ is between 10° and 40°. For example but not limited to, the tilt angle θ of the tilt and twist ion implantation 120 can be 20° in accordance with the preferred embodiment. The twist angle φ is adjusted according to a height of the fin layer 106 and spacing distances between the gate electrodes 116. The twist angle φ is between 10° and 50°. For example but not limited to, the tilt angle φ of the tilt and twist ion implantation 120 can be 25° in accordance with the preferred embodiment. As shown in FIGS. 4A and 4B, an n type dopant is implanted into the fin layer 106 by the tilt and twist ion implantation 120. Consequently, a plurality of doped regions 122 are formed in the fin layer 106, and the doped regions 122 include the n type dopant such as arsenic (As), but not limited to this. Furthermore, the doped regions 122 are respectively extended to under the gate electrodes 116 adjacent thereto, as shown in FIGS. 4A and 4B.

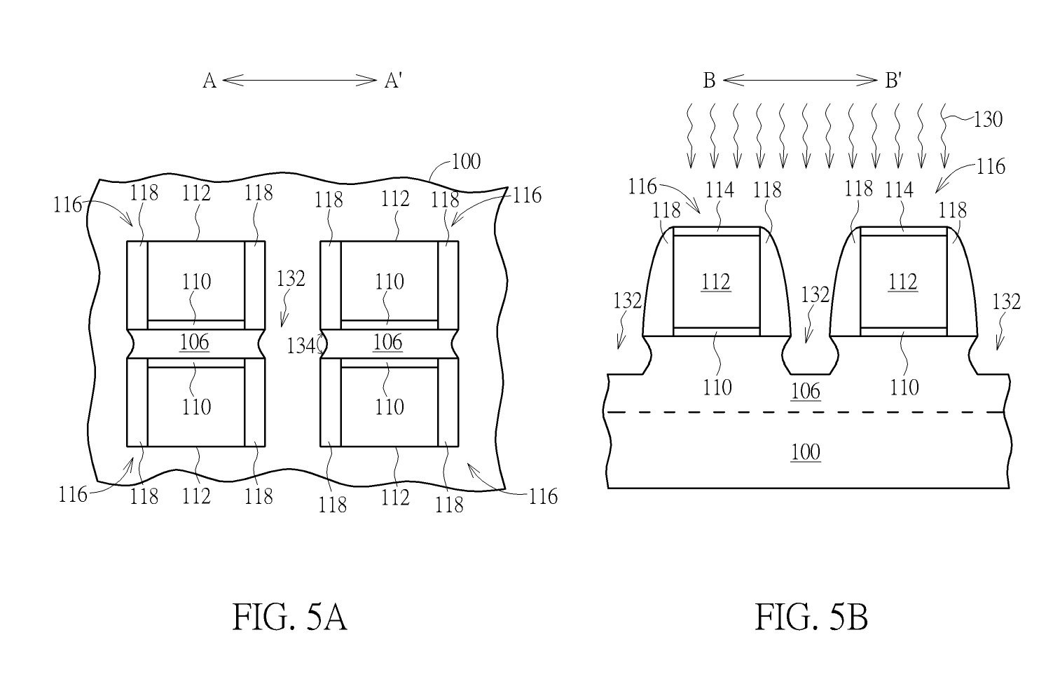

Please refer to FIGS. 5A and 5B. After forming the doped regions 122, an etching process 130 is performed to remove the doped regions 122, and thus a plurality of recesses 132 are formed in the fin layer 106. It is noteworthy that, the n type dopant, which is implanted into the fin layer 106 by the tilt and twist ion implantation 120, causes structural damages in the fin layer 106. That is, the n type dopant damages the crystal lattice of the silicon material in the doped regions 122. Moreover, the n type dopant in the doped regions 122 provides electrons during the etching process 130. Due to the structural damages and electrons provided by the n type dopant, an etching rate of the doped regions 122 is increased. In other words, the doped regions 122 are physically and chemically different from the original fin layer 106, which is not implanted. Therefore, an etching rate of the doped regions 122 is larger than an etching rate of the fin layer 106. Consequently, during the etching process 130, the doped regions 122 are removed without consuming the fin layer 106. By removing the doped regions 122, the recesses 132 are formed in the fin layer 106 as shown in FIGS. 5A and 5B. Furthermore, the recesses 132 respectively expose the fin layer 106 under the gate electrodes 116 adjacent thereto.

More important, the n type dopant is implanted into the fin layer 106 by the tilt and twist ion implantation 120 with the tilt angle θ and the twist angle φ. Therefore each of the doped regions 122 includes a special profile. Meanwhile, the etching process 130 removes the doped regions 122 along such special profile, and thus the resulted recesses 132 obtain an included angle 134 as shown in FIGS. 5A and 5B, respectively. The included angle 134 is between 100° and 140°. And each included angle 134 points to a central of the gate electrodes 116.

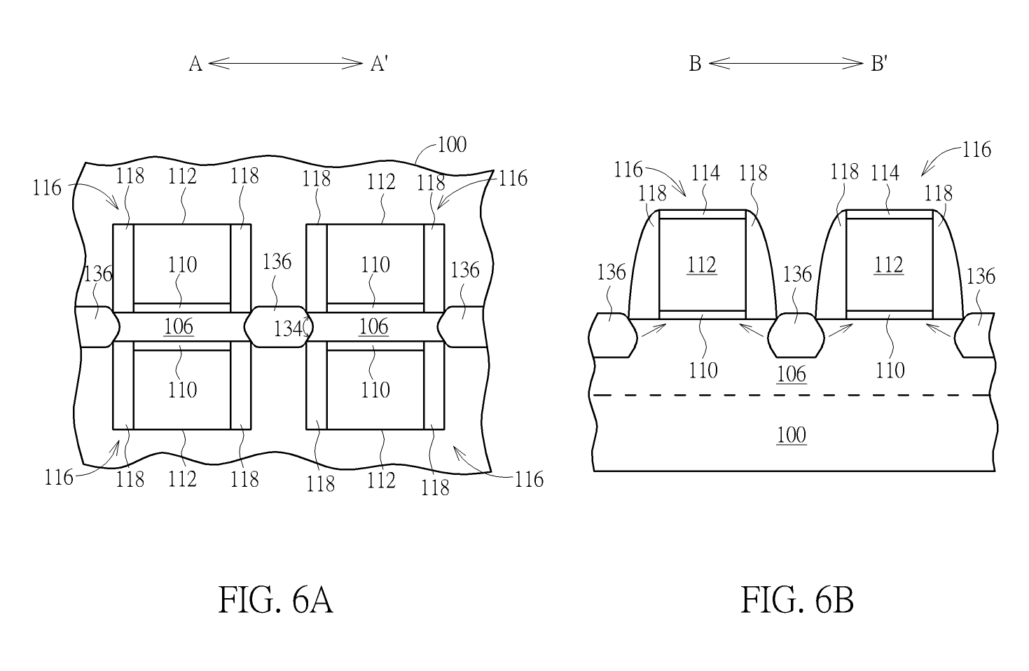

Please refer to FIGS. 6A and 6B. Next, a selective epitaxial growth (SEG) process is performed to form an epitaxial layer 136 such as an epitaxial silicon-germanium (SiGe) layer or an epitaxial silicon carbide (SiC) layer in each of the recesses 132. It is well-known to those skilled in the art that in the SEG process, the epitaxial layer 136 is to grow along a surface of the recess 132. That is, the epitaxial layer 136 is formed along the surface of the fin layer 106 exposed in the recesses 132. Therefore the epitaxial layers 136 obtain the special profile inheritably from the recesses 132. In addition, ion implantation can be performed before or after the SEG process, or a co-implant can be performed during the SEG process, and thus the doped epitaxial layers 136 respectively serve as a source/drain for a semiconductor device.

Please still refer to FIGS. 6A and 6B. Because a lattice constant of the epitaxial layers 136 is different from that of silicon, which is the main material in the fin layer 106, such characteristic is employed to cause alteration to the band structure of the silicon in the channel region. Accordingly, carrier mobility of the channel region of the semiconductor device is enhanced and thus device performance is improved. Furthermore, the epitaxial layers 136 formed in the recesses 132 inheritably obtain a hexagonal shape and a pointed end 134 toward the channel region. Because the pointed end 134 points to the central of the fin layer 106 that is where the channel region locates, effective stress to the channel region provided by the epitaxial layers 136 is further enhanced as shown in FIGS. 6A and 6B. And the carrier mobility is consequently further improved.

According to the method for manufacturing the semiconductor device provided by the present invention, the tilt and twist ion implantation is performed to form the doped regions in the fin layer. Because of the dopant implanted in the doped regions, the etching rate of the doped regions is alerted to be different from an etching rate of the fin layer. Therefore, the doped regions are easily removed by the etching process. More important, the etching process is to etch the doped regions along its profile, and thus the recesses are obtained with the special profiles. Furthermore, selective strain scheme (SSS), such as epitaxial layers capable of providing stress, is implemented in the recesses with such special profiles. Thus effective stress to the channel region provided by the selective strain scheme is further enhanced. Consequently, electrical performance of the semiconductor device is improved according to the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A method for manufacturing a semiconductor device, comprising:
providing a semiconductor substrate, the semiconductor substrate comprising at least a fin layer and a plurality of gate electrodes formed thereon;
performing a tilt and twist ion implantation to form a plurality of doped regions in the fin layer, the tilt and twist ion implantation comprising a tilt angle and the tilt angle being between 20° and 40°; and
performing an etching process to remove the doped regions to form a plurality of recesses in the fin layer.

2. The method for manufacturing the semiconductor device according to claim 1, wherein the gate electrodes covers portions of the fin layer.

3. The method for manufacturing the semiconductor device according to claim 1, wherein the tilt angle is adjusted according to a height of the gate electrodes.

4. (canceled)

5. The method for manufacturing the semiconductor device according to claim 1, wherein the tilt and twist ion implantation comprises a twist angle, and the twist angle is adjusted according to a height of the fin layer and a spacing distance between the gate electrodes.

6. The method for manufacturing the semiconductor device according to claim 5, wherein the twist angle is between 10° and 50°.

7. The method for manufacturing the semiconductor device according to claim 1, wherein the doped regions comprise an n type dopant.

8. The method for manufacturing the semiconductor device according to claim 7, wherein the n type dopant comprises arsenic (As).

9. The method for manufacturing the semiconductor device according to claim 1, wherein the doped regions are respectively extended to under the gate electrodes adjacent thereto.

10. The method for manufacturing the semiconductor device according to claim 1, wherein the recesses respectively comprise an included angle, and the included angle is between 100° and 140°.

11. The method for manufacturing the semiconductor device according to claim 1, further comprising forming an epitaxial layer in the recesses, respectively.
